(19) United States
(12) Patent Application Publication
(10) Pub. No.: US 2006/0068227 A1
(43) Pub. Date: Mar. 30, 2006

(54) Ag-based reflection film and method for preparing the same

(76) Inventors: Sadayuki Ukishima, Chiba-ken (JP); Satoru Ishibashi, Chiba-ken (JP); Shigeru Saitou, Chiba-ken (JP); Poong Kim, Chiba-ken (JP)

Correspondence Address: ARENT FOX PLLC, 1050 CONNECTICUT AVENUE, N.W., SUITE 400, WASHINGTON, DC, 20036, US

(21) Appl. No.: 11/239,686

(22) Filed: Sep. 30, 2005

(30) Foreign Application Priority Data
Sep. 30, 2004 (JP) 286141/2004

(51) Int. Cl. B32B 15/04; B32B 9/00; B32B 19/00; C23C 14/00

(52) U.S. Cl. 428/702; 428/469; 428/472; 428/698; 428/701; 204/192.15

(57) ABSTRACT

An Ag-based reflection film consists of a laminate film comprising an Ag or Ag-alloy film provided thereon with a quite thin capping layer. The Ag-based reflection film can be prepared by, for instance, forming, on a substrate, an Ag or Ag-alloy film according to the sputtering technique, while using a sputtering target, for instance, having a composition corresponding to that of the pure Ag film, and Ar gas as a sputtering gas, while adding an additional gas such as O₂, only at the initial stage of the Ag or Ag-alloy film-forming step; and then forming a quite thin capping layer, on the Ag or Ag-alloy film, according to the sputtering technique, while using a sputtering target having a composition corresponding to that of the capping layer, and Ar gas as a sputtering gas, while if necessary adding an additional gas such as O₂. The Ag-based reflection film can maintain a high reflectance without causing any deterioration thereof even under the severe conditions such as those for the hydrogen sulfide-exposure test because of the presence of a quite thin capping layer. The reflection film may be applied to, for instance, those used for display devices and optics-relating ones.

### BACKGROUND OF THE INVENTION

1. Field of the Invention

The present invention relates to an Ag-based reflection film and a method for the preparation of the same and more particularly to an Ag-based reflection film comprising an Ag or Ag-alloy thin film and a capping layer as well as a method for the preparation of the same.

2. Description of the Prior Art

The Ag or Ag-alloy thin film has long attracted special interest as a reflection film used in the display device. However, it has been known that this Ag or Ag-alloy thin film suffers from a problem of low corrosion resistance. More specifically, the Ag or Ag-alloy thin film undergoes discoloration due to the reaction with sulfur- and/or chlorine-containing components present in the air or the surrounding atmosphere, the reflectance thereof is in turn reduced and the thin film is likewise inferior in the ability to adhere to a substrate or the adhesive properties. Accordingly, an upper protective film and/or an underlying adhesive layer should be applied onto the Ag or Ag-alloy thin film.

As method for the improvement of the foregoing corrosion resistance, there has been proposed the use of a film of an alloy such as an Ag/Pd alloy or an Ag/Pd/Cu alloy as the foregoing Ag-alloy thin film (see, for instance, the patent references 1 and 2 specified below). However, a film of such an alloy does not always have satisfactorily high corrosion resistance in an atmosphere containing hydrogen sulfide and it has insufficient adhesion to a substrate. Thus, an adhesive layer consisting of, for instance, a metal oxide must be formed between the substrate and the Ag or Ag-alloy thin film.

In addition, there has also been proposed a method for preparing an Ag alloy thin film having a high reflectance, excellent adhesion to a substrate and superior corrosion resistance, while variously investigating the composition of such an alloy as well as a sputtering target for the preparation of such a thin film (see, for instance, the patent reference 3 given below). In the case of an Ag alloy thin film (an Ag/Au/Sn alloy film consisting of 0.55 at % of Au, 0.27 at % of Sn and the balance of Ag and having a thickness of 1500 Å) prepared using this target, it has improved corrosion resistance under high temperature and high humidity conditions (at 80° C. and RH of 90%) and the reduction of the reflectance thereof at a wavelength of 400 nm is minimized to a level on the order of about 3% even after 200 hours (see FIG. 1), but the reflectance thereof is significantly reduced in a test carried out in an atmosphere containing hydrogen sulfide (40° C. and RH of 80%) and the film has thus found to be insufficient corrosion resistance to hydrogen sulfide (see FIG. 2). In this respect, FIG. 1 shows the results of the corrosion resistance test observed under high temperature and high humidity conditions and more specifically, shows the reflectance (observed at wavelength ranging from 400 to 700 nm) determined immediately after the film formation (the curve a) and after 24 hours (the curve b), 90 hours (the curve c), 165 hours (the curve d) and 200 hours (the curve e) from the formation of the film, respectively, which are plotted against wavelengths. Moreover, FIG. 2 shows the results obtained in the corrosion resistance test carried out in the atmosphere containing hydrogen sulfide and more specifically, shows the reflectance (observed at wavelength ranging from 300 to 800 nm) determined immediately after the film formation (the curve a) and after one hour (the curve b), 2 hours (the curve c), 4 hours (the curve d), 8 hours (the curve e), 16 hours (the curve f) and 24 hours (the curve g) from the formation of the film, respectively, which are plotted against wavelengths.

Alternatively, there has also been known a light-reflection film having a multi-layered structure which comprises an underlying layer of an oxide, a reflection layer consisting of an Ag-alloy thin film and a capping layer (see, for instance, the patent reference 4 specified below). In this respect, the capping layer comprises at least three layers, for instance, at least one layer of an insulating material having a refractive index equal to or less than 1.7 and at least two layers of oxides containing indium and cerium and the absolute reflectance thereof is thus inevitably reduced. For this reason, the thickness distribution of each layer constituting the multi-layered structure should be made uniform and this would correspondingly increase the production cost of the light-reflection layer.

Patent Reference 1: Japanese Un-Examined Patent Publication 2000-109943 (claims);

Patent Reference 2: Japanese Un-Examined Patent Publication 2000-285517 (claims);

Patent Reference 3: Japanese Un-Examined Patent Publication 2004-197117 (claims); and

Patent Reference 4: Japanese Un-Examined Patent Publication 2003-195286 (claims).

### SUMMARY OF THE INVENTION

Accordingly, it is an object of the present invention to solve the foregoing problems associated with the conventional techniques and more specifically to provide an Ag-based reflection film which never undergoes any deterioration even under such severe conditions for the corrosion resistance test carried out, for instance, in an atmosphere containing hydrogen sulfide and which can maintain a high reflectance over an extremely long period of time as well as a method for the preparation of such a reflection film.

The inventors of this invention have variously investigated the protective films to be applied onto an Ag or Ag-alloy thin film to thus optimize a variety of preparation conditions of the same such as the selection of raw materials therefor and the thickness of the resulting protective film. As a result, the inventors of this invention have found that any deterioration of the Ag-based reflection film can completely be inhibited even under severe conditions for the corrosion resistance test carried out using an atmosphere containing hydrogen sulfide, which have been recognized to be particularly severe conditions among other conditions for other corrosion resistance tests, if using a specific protective film having a quite small thickness. In this connection, the inventors have investigated both the conductive materials required for forming electrode films and the materials for insulating films which are simply used as reflection films.

Accordingly, the Ag-based reflection film of the present invention consists of a laminate film, which comprises an Ag or Ag-alloy thin film and a quite thin capping layer applied onto the former. Thus, if a capping layer serving as a protective layer, which has a high transparency and a quite small thickness, is formed on the Ag or Ag-alloy thin film serving as a reflection layer, the resulting laminated film never undergoes any deterioration of the reflectance even in a severe and corrosive atmosphere and has improved durability. In a preferred embodiment of the present invention, the thickness of the capping layer should be minimized as small as possible such that the quantity of light absorption in the capping layer is thus minimized to a smallest possible level. To this end, it is desirable to use a material for a capping layer having a high transmittance.

The foregoing Ag or Ag-alloy film is preferably the one selected from the group consisting of pure Ag thin film, and Ag alloy thin film such as Ag/Au alloy thin film, Ag/Au/Sn alloy thin film, Ag/Pd alloy thin film and Ag/Pd/Cu alloy thin film. The most excellent thin film is a pure Ag film from the viewpoint of the reflectance.

In a preferred embodiment of the present invention, the foregoing Ag-alloy thin film is an Ag/Au/Sn alloy thin film, which comprises Ag as a principal component, 0.1 to 4.0 at % of Au and 0.1 to 2.5 at % of Sn. This Ag-alloy thin film has a reflectance, as determined in the visible light range, of not less than 90% and has excellent corrosion resistance and good adhesion to a substrate such as a glass substrate. The reflection film of an Ag-alloy, whose composition is beyond the range specified above, can never satisfy all of the requirements for the reflectance, corrosion resistance and adhesion to substrates. In this reflection film, the improvement of the corrosion resistance of the film is mainly due to alloying effect of Au in the film and the application of a capping layer serving as a protective film, while the improvement of the adhesion of the film to the substrate is mainly due to alloying effect of Sn in the film.

The foregoing Ag/Au/Sn alloy film may likewise be one which further comprises oxygen in an amount ranging from 0.1 to 3.0 at %. The alloy film containing oxygen in the amount specified above is excellent in the adhesion to a substrate.

The foregoing capping layer is preferably constituted by a film made of a material selected from the group consisting of metal oxides such as ITO, ZnO, IZO and SnO₂, tantalum nitride, silicon oxide, aluminum oxide, titanium oxide, tantalum oxide, silicon nitride, aluminum nitride and titanium nitride.

It is in general sufficient that the thickness of the capping layer ranges from 3 to 50 nm. The film thickness of the capping layer is preferably not less than 3 nm and less than 15 nm if the material for the capping layer is a metal oxide. The thinner the thickness of the capping layer, the better the reflection characteristics of the same (see FIG. 3 as will be described in detail later) and the intended purpose of the present invention can sufficiently be accomplished when the thickness of the capping layer falls within the range specified above. Moreover, regarding the durability, the reflection film or the capping layer does not undergo any change in the reflectance with the elapse of time even in an atmosphere containing hydrogen sulfide inasmuch as the thickness of the capping layer falls within the range specified above (see FIG. 4 as will be described in detail later).

The foregoing capping layer is preferably constituted by a film prepared by the vacuum processing method such as the vacuum evaporation technique, the sputtering technique or the CVD technique.

The Ag-based reflection film of the present invention is one which is subjected to an after-annealing treatment in the air, in a vacuum or in an inert gas atmosphere. This would result in the improvement of the transmittance of the capping layer and the progress of the crystallization of the Ag or Ag-alloy thin film and accordingly, a stabilized film can be provided.

The method for the preparation of an Ag-based reflection film according to the present invention comprises the steps of forming, on the surface of a substrate, an Ag or Ag-alloy thin film according to the sputtering technique, while using a sputtering target having a composition corresponding to that of the foregoing pure Ag film or an Ag-alloy film, and a sputtering gas consisting of Ar gas, while adding, as an additional gas, at least one oxygen-containing gas selected from the group consisting of O₂, H₂O, and H₂+O₂ only at the initial stage of the film-forming step; and then forming a quite thin capping layer, on the Ag or Ag-alloy thin film thus formed, according to the sputtering technique, while using a sputtering target having a composition corresponding to that of the capping layer, and a sputtering gas consisting of Ar gas, while if necessary adding, as an additional gas, at least one gas selected from the group consisting of O₂, H₂O, H₂+O₂ and N₂.

After the quite thin capping layer is thus formed on the Ag or Ag-alloy thin film according to the foregoing procedures, the resulting assembly is preferably subjected to an annealing treatment in the air, in a vacuum or an inert gas atmosphere. Such an annealing treatment after the formation of such a film is not necessarily carried out, but the annealing treatment would permit the improvement of the transmittance of the capping layer and the progress of the crystallization of the Ag or Ag-alloy thin film and accordingly, the resulting film is considerably stabilized.

The Ag-based reflection film according to the present invention never undergoes any deterioration even under such severe conditions for the corrosion resistance test carried out, for instance, in an atmosphere containing hydrogen sulfide and can maintain a high reflectance over an extremely long period of time and the method of the present invention permits the preparation of such an excellent Ag-based reflection film.

### BRIEF DESCRIPTION OF THE DRAWINGS

FIG. 1 is a graph showing the changes, with time, of the reflectance observed for a conventional Ag-alloy thin film (an Ag/Au/Sn alloy thin film) as determined under high temperature and high humidity conditions, which are plotted as a function of wavelength.

FIG. 2 is a graph showing the changes, with time, in the reflectance observed for a conventional Ag-alloy thin film (an Ag/Au/Sn alloy thin film) as determined in an atmosphere containing hydrogen sulfide, which are plotted as a function of wavelength.

FIG. 3 is a graph showing the influence of the capping layer thicknesses on the reflectance observed for the Ag-based reflection films prepared in Example 1, in which the reflectance observed for the Ag-based reflection film is plotted as functions of wavelength.

FIG. 4 is a graph showing the changes, with time, of the reflectance observed for the Ag-based reflection films prepared in Example 1, which are determined after a hydrogen sulfide-exposure test and the determination is carried out to evaluate the durability of the film.

FIG. 5 is a diagram schematically showing the structure of an in-line type sputtering equipment used in Examples.

FIG. 6 is a graph showing the influence of the capping layer thicknesses on the reflectance observed for the Ag-based reflection films prepared in Example 2, in which the reflectance observed for Ag-based reflection films is plotted as functions of wavelength.

FIG. 7 is a graph showing the influence of the capping layer thicknesses on the reflectance observed for the Ag-based reflection films prepared according to the procedures similar to those used in Example 2 except that the pressure during film-formation is changed, in which the reflectance observed for the Ag-based reflection films is plotted as functions of wavelength.

FIG. 8 is a graph showing the changes, with time, of the reflectance observed for the Ag-based reflection films prepared in Example 2, which are determined after a hydrogen sulfide-exposure test and the determination is carried out to evaluate the durability of the film.

FIG. 9 is a graph showing the influence of the capping layer thicknesses on the reflectance observed for the Ag-based reflection films prepared in Example 3, in which the reflectance observed for the Ag-based reflection films is plotted as functions of wavelength.

FIG. 10 is a graph showing the reflectance change for the film: ITO capping layer (5 nm)/Ag-alloy film (150 nm) prepared in Example 1 having a two-layered structure, before and after the annealing treatment.

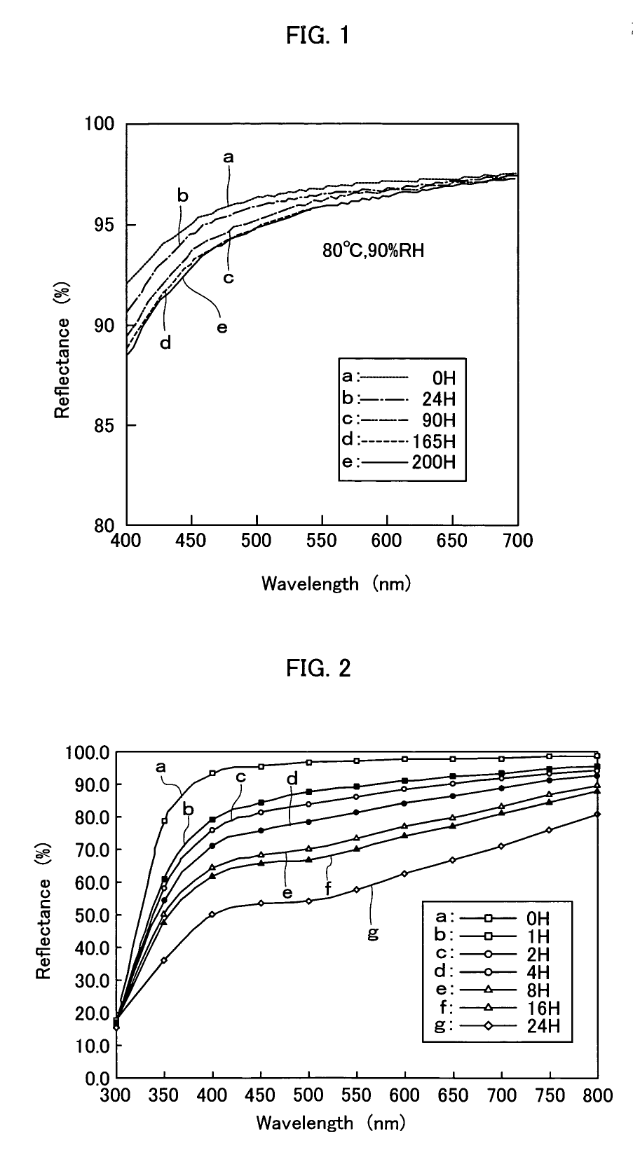

### DESCRIPTION OF THE PREFERRED EMBODIMENTS

The lower layer of the Ag-based reflection film according to the present invention is not restricted to any specific one insofar as it is an Ag or Ag-alloy film having high transmittance and excellent corrosion resistance, which can be prepared using commercially available materials according to any known method and the lower layer is preferably selected from the group consisting of, for instance, pure Ag films and alloy films such as Ag/Au alloy films, Ag/Au/Sn alloy films, Ag/Pd alloy films and Ag/Pd/Cu alloy films.

As the Ag/Au/Sn alloy films usable herein, there may be listed, for instance, those listed above. Such Ag/Pd alloy films usable herein may be, for instance, films of alloys each comprising Ag as the principal component and 0.5 to 4.9 at % of Pd. As the Ag/Pd/Cu alloy films usable herein, there may be listed, for instance, films of alloys each of which comprises the foregoing Ag/Pd alloy components and further comprises 0.1 to 3.5 at % of Cu, and films of alloys each of which comprises Ag as the principal component, 0.5 to 3.0 at % of Pd and 0.1 to 3.0 at % of Cu.

In the present invention, the capping layer for protecting the Ag or Ag-alloy film may be any metallic film insofar as it can protect the Ag or Ag-alloy film in such a manner that the latter never undergoes any deterioration of its reflectance even in a severe corrosion resistance test carried out in an atmosphere containing hydrogen sulfide and it can maintain a high reflectance of the alloy film. As has been discussed above, the capping layer may be an extremely thin film made of, for instance, a material selected from the group consisting of a variety of metal oxides and nitrides.

Among the materials which can be used for constituting the capping layer, those having conductivity, for instance, metal oxides such as ITO, ZnO, IZO and SnO₂ permit the formation of transparent conductive film and can be used as reflection electrodes. Moreover, films consisting of, for instance, nitrides and oxides of Si, Al, Ti and Ta are, for instance, insulating thin films and therefore, the applications thereof are limited to those as reflection films. A large amount of oxygen should be used when preparing films starting from oxides of, for instance, Si, Al, Ti and Ta and therefore, the preformed Ag film may suffer from oxidation in the processes using plasma such as the sputtering technique and the plasma CVD technique. Accordingly, the techniques which do not require the use of plasma such as the vapor deposition techniques can suitably be used when preparing an oxide film serving as a capping layer. In this connection, however, the transparent conductive film such as an ITO film can be prepared according to the sputtering technique while adding a small amount of oxygen gas. Therefore, the preformed Ag or Ag-alloy film never undergoes any deterioration through oxidation and the film-forming processes applicable herein are not restricted to specific ones at all.

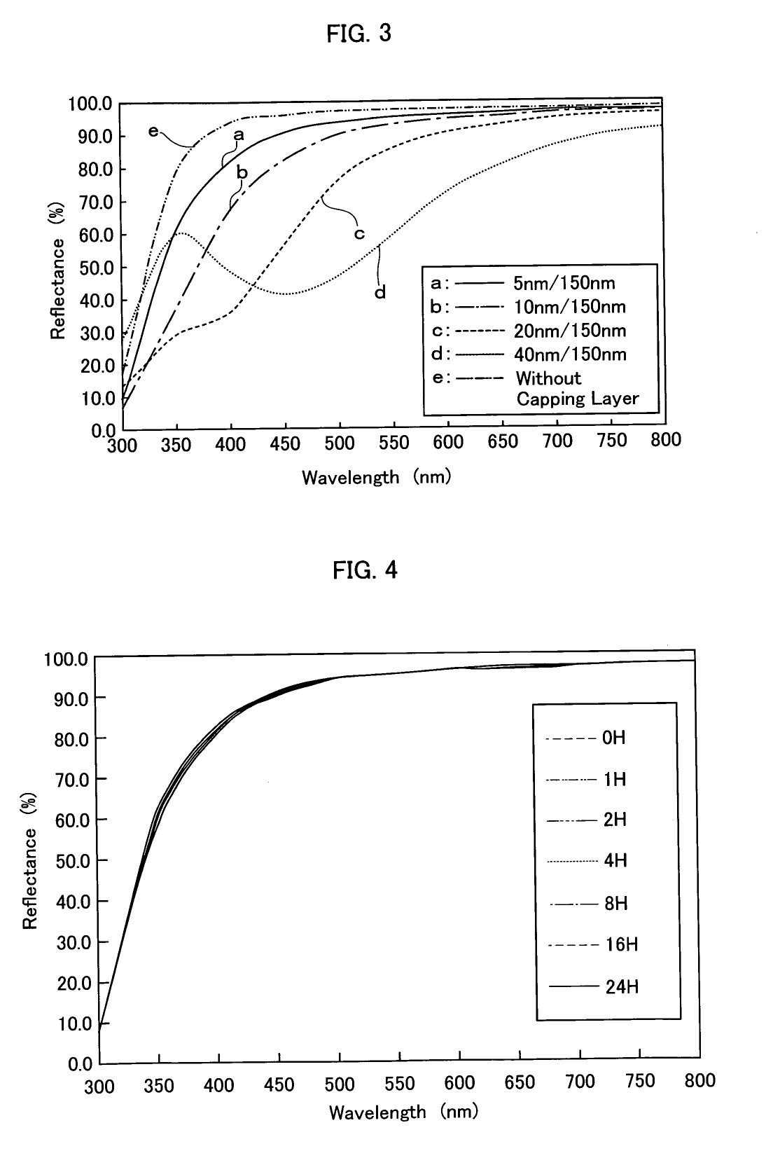

The thickness of the capping layer is preferably not less than 3 nm and less than 15 nm, more preferably 3 to 10 nm and most preferably 3 to 5 nm, when using a conductive metal oxide as a material therefor. On the other hand, when using an insulating metal nitride or a metal oxide as a material for the capping layer, the thickness of the capping layer in general ranges from 3 to 50 nm, preferably 3 to 15 nm, more preferably 3 to 10 nm and most preferably 3 to 5 nm. When inspecting the resulting capping layer for the correlation between the film thickness and the transmittance of the layer, the reflectance of the laminate film: capping layer/reflection film or the durability thereof, it has been found that the thinner the capping layer, the better the reflection characteristics thereof (see FIG. 3 as will be described in detail later). The resulting film was further inspected for any change, with the elapse of time, of the reflectance within an atmosphere containing hydrogen sulfide for the evaluation of the durability of the capping layer and as a result, it was found that the film did not undergo any change in the reflectance and had sufficiently high durability inasmuch as the film had a thickness falling within the range specified above (see the results plotted on FIG. 4 as will be detailed later).

Moreover, the capping layer preferably consists of a thin film prepared according to any vacuum process such as the vacuum evaporation technique, the sputtering technique and the CVD technique under the known film-forming conditions. However, any wet technique cannot be used herein, since the thickness of the capping layer should be controlled at the level on the order of nanometer. For this reason, only the film-forming processes which make use of a vacuum can be used as the processes for forming such a capping layer.

The capping layer can be prepared according to the vacuum evaporation technique or the CVD technique (in particular, the plasma CVD technique) practiced under the known conditions and particular examples thereof will be given below:

(1) Process Conditions for Forming ITO Films According to Vacuum Evaporation Technique

Mode: Electron Beam (EB) Vacuum Evaporation;

Material: ITO Tablet (containing 10% by mass of SnO₂);

Pressure: 5×10⁻³ Pa; Electric Voltage: 5 kV; Electric Current: 50 mA;

Flow Rate of O₂: 1 SCCM; and Deposition Rate: 0.5 nm/sec.

An ITO film having a thickness of 5, 10 or 20 nm can be prepared under the foregoing film-forming conditions.

(2) Process Conditions for Forming SiO₂ Films According to Vacuum Evaporation Technique

Mode: Electron Beam (EB) Vacuum Evaporation;

Material: SiO₂ Tablet; Pressure: 2×10⁻³ Pa; Electric Voltage: 5 kV;

Electric Current: 100 mA; and Deposition Rate: 0.5 nm/sec.

An SiO₂ film having a thickness of 5, 10, 20 or 40 nm can be prepared under the foregoing film-forming conditions.

(3) Process Conditions for Forming SiNₓ Films According to Plasma CVD Technique

Source of Electricity: RF Power Source (13.56 MHz); RF Power: 100 W;

Flow Rate of SiH₄: 5 SCCM; Flow Rate of N₂: 100 SCCM;

Film-Forming Temperature: 100° C.; Pressure during Film-Formation: 100 Pa; and

Deposition Rate: 0.2 nm/sec.

An SiNₓ film having a thickness of 5, 10, 20 or 40 nm can be prepared under the foregoing film-forming conditions.

Each film formed according to the foregoing procedures did not show any deterioration of the reflectance as demonstrated in the test as detailed in the following Examples in which the film was exposed to an atmosphere containing hydrogen sulfide.

The resulting Ag-based reflection film is preferably subjected to an after-annealing treatment carried out in the air, in a vacuum or an inert gas atmosphere so that the transmittance of the capping layer can be improved and that the crystallization of the lower Ag or Ag-alloy film can be accelerated to thus form a stabilized film. For instance, this annealing treatment is preferably carried out by, for instance, heating the film to a temperature ranging from 200 to 300° C. for 0.5 to 2 hours.

As has been described above, when preparing the Ag-based reflection film of the present invention according to, for instance, the sputtering technique, the method comprises the steps of forming, on the surface of a substrate, an Ag or Ag-alloy film according to the sputtering technique, while using a sputtering target having a composition corresponding to that of the foregoing Ag or Ag-alloy film, and a sputtering gas consisting of Ar gas, while adding, as an additional gas, at least one oxygen-containing gas selected from the group consisting of O₂, H₂O, and H₂+O₂ only at the initial stage of the Ag or Ag-alloy film-forming step; and then forming a quite thin capping layer, on the Ag or Ag-alloy film thus formed, according to the sputtering technique, while using a sputtering target having a composition corresponding to that of the capping layer, and a sputtering gas consisting of Ar gas, while if necessary adding, as an additional gas, at least one gas selected from the group consisting of O₂, H₂O, H₂+O₂ and N₂. In this case, the film-formation can be practiced at a temperature ranging from room temperature to 350° C. In this connection, the sputtering targets containing Sn may form a film containing an SnO₂ component among others when using a trace amount of an additional gas such as O₂, H₂O, and H₂+O₂. The optimum pressure of these additional gases may be on the order of about 2.7×10⁻³ Pa to 6.7×10⁻² Pa. The SnO₂ component may serve as a binder for the adhesion of the film to the substrate and therefore, the use of such sputtering target having an Sn content would easily permit the formation of an Ag or Ag-alloy film excellent in the adhesive characteristics. In this respect, the introduction of the additional gas or such an oxidizing agent is preferably carried out only in the proximity to the boundary between the substrate and the film during forming (or only during the initial stage of the film-formation) from the viewpoint of the reflectance and the resistivity of the resulting Ag or Ag-alloy film.

The substrate usable in the present invention may appropriately be selected while taking into consideration each particular application of the resulting Ag-based reflection film and specific examples thereof are those made of glass and silicon and effectively used herein also include plastic films.

The present invention has been described while mainly taking the applications of the Ag or Ag-alloy film as reflection films by way of example. However, the resulting Ag-based reflection film is one excellent in the corrosion resistance even under severe conditions while maintaining a high reflectance and accordingly, the film may likewise be effective as a reflector film having a high reflectance usable in the field of optics, a reflector film for back lights and LCD and a reflecting electrode film used for LCD and organic EL.

The present invention will hereunder be described in more detail with reference to the following Examples while referring to the accompanying drawings as well.

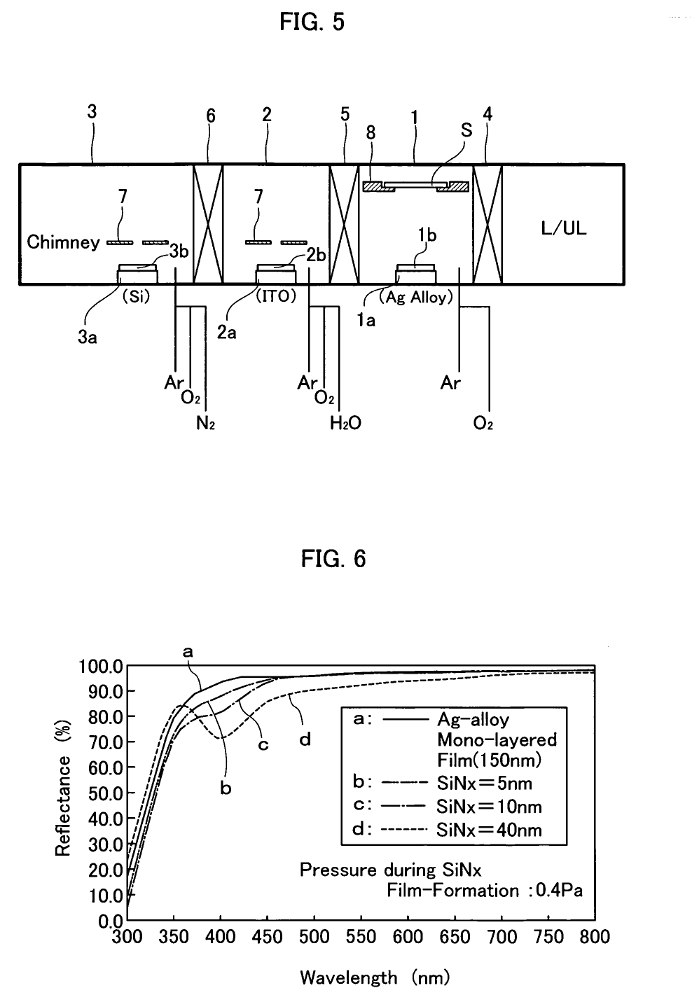

First of all, referring to FIG. 5, there is depicted a schematic structure of an in-line type sputtering equipment used in the following Examples. This sputtering equipment comprises first to third sputtering chambers 1 to 3. Each sputtering chamber is separated from other chambers by gate valves 4, 5 and 6. The gate valve 4 separates an introduction chamber (L/UL) from the sputtering chamber 1; the gate valve 5 separates the sputtering chamber 1 from the sputtering chamber 2; and the gate valve 6 separates the sputtering chamber 2 from the sputtering chamber 3. Each sputtering chamber is so designed that it may independently be connected to an evacuation system and a gas-introduction system and the introduction chamber may likewise be provided with an evacuation system. The gas-introduction system is so designed that it can introduce other gases such as O₂, H₂O, H₂+O₂ and N₂ in addition to the Ar gas serving as a sputtering gas. Each sputtering chamber is provided with cathode electrode 1a, 2a, 3a arranged within the chamber and each equipped with a corresponding magnetic circuit and targets 1b, 2b, 3b are attached to and positioned on these cathode electrodes, respectively. The target 1b arranged within the first sputtering chamber 1 may be an Ag or Ag-alloy target for forming an Ag or Ag-alloy film; the target 2b arranged within the second sputtering chamber 2 may be a metal oxide target represented by ITO; and the target 3b arranged within the third sputtering chamber 3 may be an Si target or a metal target. The equipment is further so designed that a DC bias is applied to each of these targets. Each of these targets usable herein may be one prepared from desired metals properly selected while taking into consideration the composition of an intended Ag or Ag-alloy film or a capping layer.

Chimneys each having an opening of a desired width, for instance, a width of about 20 mm are arranged, along the running direction of the substrate, above the targets 2 and 3 positioned in the second and third sputtering chambers so that the thickness of the thin film is controlled.

In FIG. 5, the reference numeral 8 represents a tray for conveying a substrate or a substrate support and S denotes a substrate.

### EXAMPLE 1

<ITO Capping Layer>

An Ag-alloy target which comprised Ag as a principal component, 0.55 at % (1.0% by mass) of Au and 0.27 at % (0.3% by mass) of Sn was set, as the target 1b, on the cathode 1a arranged within the first sputtering chamber 1, while an ITO (containing 10% by mass of SnO₂) target was set on the cathode 2a arranged within the sputtering chamber 2 as the target 2b.

To the first sputtering chamber 1, there were introduced 200 SCCM of Ar gas and 0.5 SCCM of oxygen gas (a partial pressure of O₂ of 6.65E-3 Pa) and then a DC power of 2000 W (a power density of 3.88 W/cm²) was applied to the target 1b. In this respect, the pressure during sputtering film-formation was set at a level of about 0.667 Pa. The tray 8 supporting a cleaned glass substrate S (Corning 1737) was transferred to the first sputtering chamber 1 through the introduction chamber L/UL, followed by passing the substrate through the first chamber 1 at a conveying speed of 31 cm/min at room temperature to thus form a film on the substrate. In this respect, it was found that an Ag-alloy film having a thickness of 50 nm was formed on the substrate at an instance when the tray 8 passed through the target 1b. Then the introduction of the oxygen gas was discontinued, the electric discharge was continued in an atmosphere containing only Ar gas while conveying the tray 8 in the opposite direction within the chamber 1 at a conveying speed of 31 cm/min, the tray 8 was again moved along the running direction after the tray 8 passed through the target 1b to thus continue the film-forming operation till the thickness of the resulting film reached 100 nm. Thus, an Ag-alloy film having an overall thickness of 150 nm could be formed on the substrate S.

Then, to the second sputtering chamber 2, there was introduced 200 SCCM of Ar gas, the pressure during sputtering film-formation in the chamber was controlled to a level on the order of 0.667 Pa and then a DC power of 580 W (a power density of 1 W/cm²) was applied to the target 2b. Thereafter, the tray 8 was transferred from the sputtering chamber 1 to the sputtering chamber 2, followed by running the substrate through the second chamber 2 at a conveying speed of 40 cm/min at room temperature to thus form an ITO film as a capping layer having a thickness of 5 nm on the Ag-alloy film previously formed on the substrate. After interrupting the discharge, the Ar gas-supply was discontinued, the tray 8 was brought back to the introduction chamber L/UL to thus remove the substrate. Thus, a two-layered film was prepared, which comprised an ITO capping layer (thickness: 5 nm) and an Ag-alloy film (thickness: 150 nm).

The same procedures used above were repeated except that the substrate-conveying speed in the second sputtering chamber 2 was variously adjusted to thus form an Ag-alloy film (thickness: 150 nm) which was provided thereon with an ITO capping layer having a thickness of 10, 20 or 40 nm.

The resulting two-layered films each comprising an ITO capping layer and an Ag-alloy film were inspected for the absolute reflectance (at a wavelength range of from 300 to 800 nm) and the results thus obtained were compared with those observed for the Ag-alloy film free of any capping layer. The results thus obtained are plotted on FIG. 3. The data plotted on FIG. 3 clearly indicate that the reflectance was reduced as the thickness of the ITO film as a capping layer increases. In addition, it was also found that the ITO film having a thickness of 5 nm showed the lowest reduction of the reflectance.

The Ag-alloy film on which an ITO capping layer had been formed was used in a test in which the film was exposed to an atmosphere containing hydrogen sulfide. Each sample was allowed to stand under the following conditions: an H₂S concentration of 10 ppm; a temperature of 40° C.; and a humidity of 80%, for 1, 2, 4, 8, 16 and 24 hours and then the absolute reflectance of each sample was determined (at a wavelength ranging from 300 to 800 nm). The results thus obtained are plotted on FIG. 4. The data thus obtained approximately lie on the same curve although the samples were allowed to stand over different time periods and therefore, each curve was not separately depicted by, for instance, dotted line, a chain line or the like. However, these data clearly indicate that the Ag-alloy film provided thereon with an ITO capping layer never undergoes any deterioration of the reflectance thereof even after 24 hours and that the film is quite excellent in the corrosion resistance.

Alternatively, the same procedures used above were repeated except for using a target comprising Ag as a principal component, 0.28 at % (0.5% by mass) of Au and 0.46 at % (0.5% by mass) of Sn to thus form, on a glass substrate, two-layered film comprising an Ag-alloy film (having a thickness of 150 nm) and an ITO capping layer (having a thickness of 5 nm) and then the resulting sample was subjected to the same hydrogen sulfide-exposure test used above over 24 hours. As a result, it was found that the sample did not show any change in its reflectance with time and that the sample was thus excellent in the corrosion resistance.

In the foregoing method, an in-line type film-forming method was used, but these films may likewise be formed using a film-forming equipment of the batch type one in which a substrate is fixed; a multi-chamber cluster type one and a substrate-rotation type one.

### EXAMPLE 2

<SiNₓ Capping Layer>

As in the case of Example 1, an Ag-alloy target which comprised Ag as a principal component, 0.55 at % (1.0% by mass) of Au and 0.27 at % (0.3% by mass) of Sn was set, as the target 1b, on the cathode 1a arranged within the first sputtering chamber 1, while an Si target was set on the cathode 3a arranged within the sputtering chamber 3 as the target 3b.

An Ag-alloy film was formed on a glass substrate by repeating the same procedures used in Example 1 except for using the foregoing Ag-alloy target in a thickness of 150 nm and then the substrate was transferred to the second sputtering chamber 2. Thereafter, to the third sputtering chamber, there were introduced 60 SCCM of Ar gas and 40 SCCM of N₂ gas, the pressure during sputtering film-formation was set at a level of 0.4 Pa and a DC power of 2000 W (a power density of 3.88 W/cm²) was applied to the Si target. Then the gate valve 6 positioned between the second sputtering chamber 2 and the third sputtering chamber 3 was opened and the tray 8 supporting the substrate was moved through the chamber 3 at a conveying speed of 80 cm/min to form a film at room temperature and to thus give an SiNₓ film having a thickness of 5 nm as a capping layer, on the Ag-alloy film previously formed on the substrate. After interrupting the discharge, the gas-supply was discontinued, the tray 8 was brought back to the introduction chamber L/UL to thus remove the substrate. Thus, a two-layered film was prepared, which comprised an SiNₓ capping layer (thickness: 5 nm) and an Ag-alloy film (thickness: 150 nm).

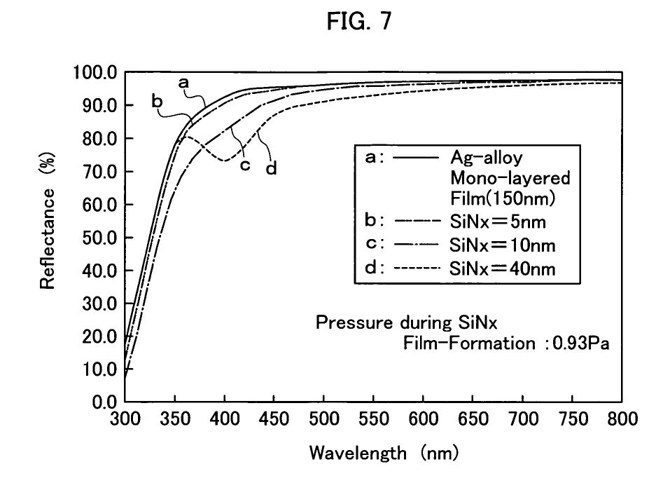

The same procedures used above were repeated except that the conveying speed of the tray was variously changed to thus form Ag-alloy films each provided thereon with an SiNₓ capping layer having a thickness of 10 nm or 40 nm. The resulting two-layered film comprising the SiNₓ capping layer and the Ag-alloy film was inspected for the dependency of the reflectance observed for the film on the thickness of the SiNₓ film. FIG. 6 shows the results thus obtained. Alternatively, the same procedures used above were likewise repeated except that the pressure during the formation of an SiNₓ film was set at a level of 0.93 Pa to thus form a two-layered film comprising the SiNₓ capping layer and an Ag-alloy film. The resulting two-layered film comprising the SiNₓ capping layer and the Ag-alloy film was inspected for the dependency of the reflectance observed for the film on the thickness of the SiNₓ film. FIG. 7 shows the results thus obtained. As will be seen from the data plotted on FIGS. 6 and 7, in the case of the capping layer consisting of an SiNₓ film, the thinner the thickness of the capping layer, the better the reflecting characteristics of the resulting film, like the ITO capping layer. The pressure during the SiNₓ film-formation of 0.93 Pa was found to be rather preferred since the resulting film showed a less deteriorated reflectance, on the shorter wavelength side. This would be due to the difference in the refractive index between these films prepared under different pressures during film-formation.

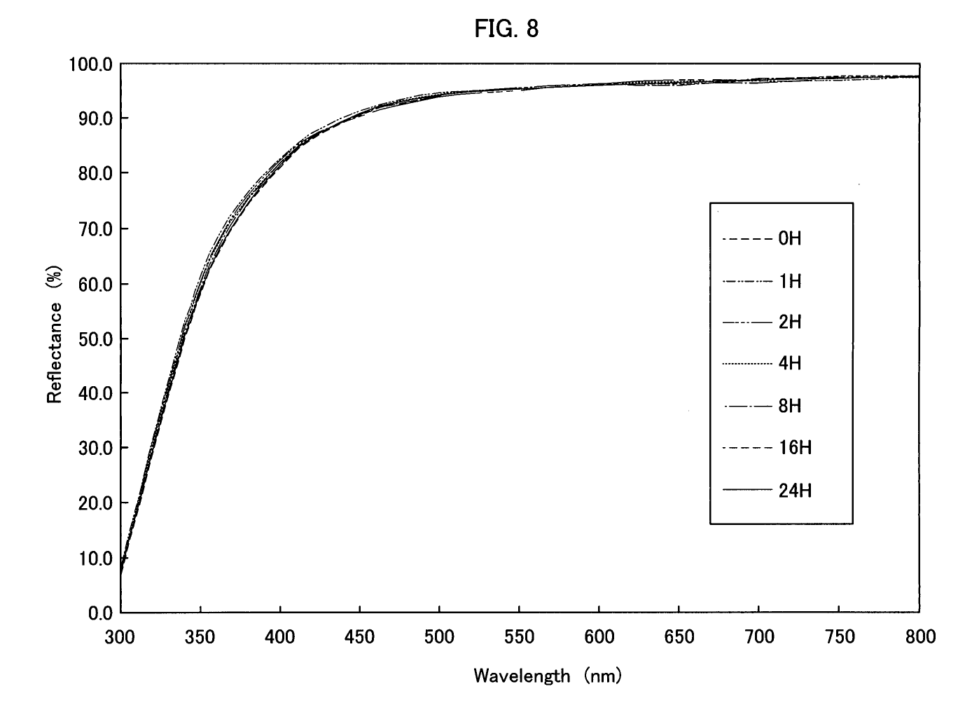

The resulting Ag-alloy film on which an SiNₓ capping layer had been formed was used in a test in which the film was exposed to an atmosphere containing hydrogen sulfide. The sample was allowed to stand under the following conditions: an H₂S concentration of 10 ppm; a temperature of 40° C.; and a humidity of 80%, for 1, 2, 4, 8, 16 and 24 hours and then the absolute reflectance of each sample was determined (at a wavelength ranging from 300 to 800 nm). The results thus obtained are plotted on FIG. 8. The data thus obtained approximately lie on the same curve although the samples were allowed to stand over different time periods. As a result, it could be concluded that the Ag-alloy film provided thereon with an SiNₓ capping layer never undergoes any deterioration of the reflectance thereof even after 24 hours and that the film is quite excellent in the corrosion resistance.

### EXAMPLE 3

<SiOₓ Capping Layer>

An Ag-alloy target which comprised Ag as a principal component, 0.55 at % (1.0% by mass) of Au and 0.27 at % (0.3% by mass) of Sn was set, as the target 1b, on the cathode 1a arranged within the first sputtering chamber 1, while an Si target was set on the cathode 3a arranged within the sputtering chamber 3 as the target 3b.

An Ag-alloy film was formed on a glass substrate by repeating the same procedures used in Example 2 except for using the foregoing Ag-alloy target in a thickness of 150 nm and then the substrate was transferred to the second sputtering chamber 2. Thereafter, to the third sputtering chamber, there were introduced 70 SCCM of Ar gas and 30 SCCM of O₂ gas, the pressure during sputtering film-formation was set at a level of 0.4 Pa and a DC power of 2000 W was applied to the Si target. Then the gate valve 6 positioned between the second sputtering chamber 2 and the third sputtering chamber 3 was opened and the tray 8 supporting the substrate was moved through the chamber 3 at a conveying speed of 80 cm/min to form a film at room temperature and to thus give an SiOₓ film having a thickness of 5 nm as a capping layer, on the Ag-alloy film previously formed on the substrate. After interrupting the discharge, the gas-supply was discontinued, the tray 8 was brought back to the introduction chamber L/UL to thus remove the substrate. Thus, a two-layered film was prepared, which comprised an SiOₓ capping layer (thickness: 5 nm) and an Ag-alloy film (thickness: 150 nm).

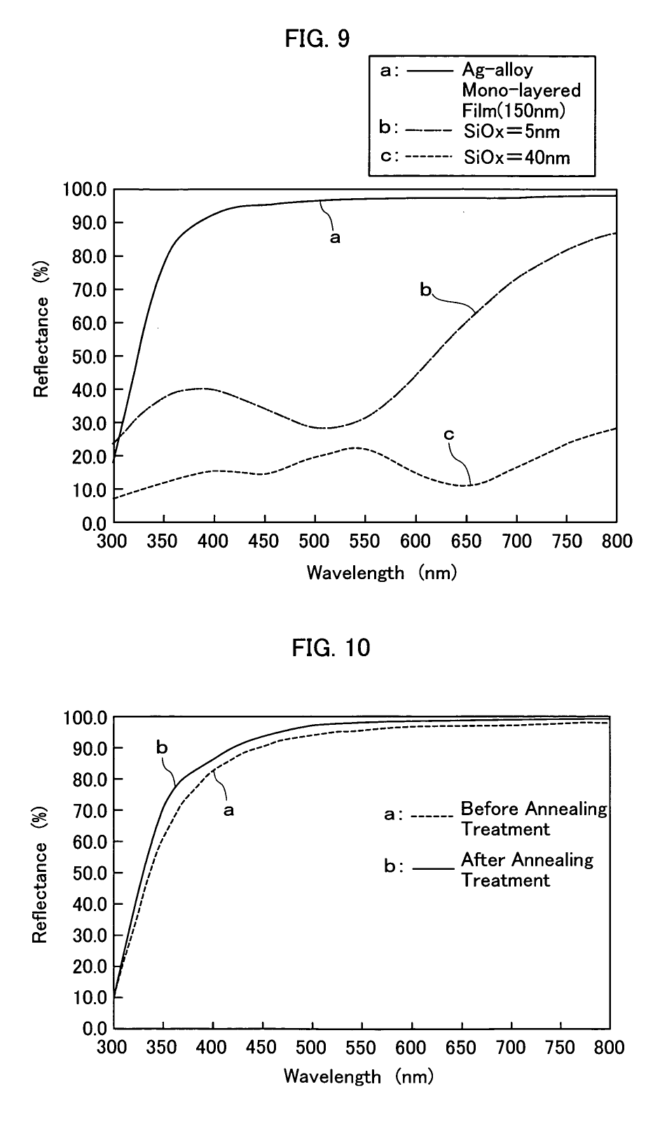

The same procedures used above were repeated except that the conveying speed of the tray was changed to thus form an Ag-alloy film provided thereon with an SiOₓ capping layer having a thickness of 40 nm. The resulting two-layered film comprising the SiOₓ capping layer and the Ag-alloy film was inspected for the dependency of the reflectance observed for the film on the thickness of the SiOₓ film. FIG. 9 shows the results thus obtained.

As will be seen from the data plotted on FIG. 9, the reflectance (as determined at a wavelength ranging from 300 to 800 nm) of the two-layered film comprising an SiOₓ capping layer and an Ag-alloy film was found to be substantially deteriorated as compared with the mono-layered Ag film (having a thickness of 150 nm), unlike the film provided thereon with an SiNₓ capping layer prepared in Example 2. It would be concluded that this is because the foregoing process requires the use of a large amount of oxygen gas and the Ag-alloy film is thus oxidized by the action of the oxygen plasma.

In the process wherein a film was formed through the sputtering technique while introducing O₂ gas above an Ag-alloy film, SiOₓ capping layers were formed while variously changing the partial pressure of the O₂ gas to be introduced into the sputtering chamber 3 to thus determine the upper limit of the O₂ gas partial pressure at which the Ag-alloy film never underwent any oxidation. As a result, the upper limit of the O₂ gas partial pressure was found to be 0.065 Pa and therefore, when the capping layer was prepared at an oxygen partial pressure of not more than 0.065 Pa, the Ag-alloy film never underwent any oxidation and the resulting two-layered film did not show any deterioration of the reflectance at all. Thus, it was found that the oxide film formed at an oxygen partial pressure of not more than 0.065 Pa could satisfactorily be used as a capping layer for the Ag-alloy film.

### EXAMPLE 4

<Annealing Treatment After Film-Formation>

The two-layered film comprising an ITO capping layer (5 nm) and an Ag-alloy film (150 nm) prepared in Example 1 was subjected to an annealing treatment at a temperature of 250° C. for one hour in the air. In this respect, the two-layered film was inspected for the reflectance (as determined at a wavelength ranging from 300 to 800 nm) before and after the annealing treatment. The results thus obtained are plotted on FIG. 10. It was thus found that the annealing treatment permitted the improvement of the reflectance by about 2 to 4%. This would be because the transmittance of the ITO capping layer was improved, the crystallization of the Ag-alloy film was accelerated by the annealing treatment, the flatness of the surface thereof was in turn improved and the reflectance of the film was accordingly improved.

In the foregoing Examples 2 and 3, the method for the preparation of Ag-based reflection film is described while taking films formed at a substrate temperature equal to room temperature by way of example, but it was found that films each having a high reflectance like the film prepared in Example 4 could be prepared even if the film-formation was carried out while heating the substrate or a film was first formed at room temperature and then subjected to an annealing treatment as in the case of Example 4. The same results were obtained when the films were prepared at a temperature ranging from room temperature to 350° C. When the film was annealed, the reflectance of the film was improved by about 2 to 3% as compared with that observed for the film prepared at room temperature and free of any annealing treatment.

In the foregoing Examples, the present invention has been described while taking note of the Ag/Au/Sn alloy films as the Ag-alloy film, but the reflectance of the pure Ag film, Ag/Pd alloy film, Ag/Pd/Cu alloy film and Ag/Au alloy film as underlying layers are not deteriorated even after the hydrogen sulfide-exposure test and can maintain their high reflectance even when applying, onto these films, a quite thin film of SiNₓ or SiOₓ as a capping layer, as in the case of the Ag/Au/Sn alloy films.

Moreover, the results similar to those described above can be obtained when using a film of, for instance, AZO, IZO or SnO₂ in addition to the foregoing ITO film as a capping layer. The nitride film may likewise be formed using a target of, for instance, Al, Ti or Ta in addition to the foregoing Si target and these nitride films likewise show a capping effect identical to that accomplished above.

As has been described above in detail, the present invention permits the preparation of an Ag-based reflection film which can maintain a high reflectance without causing any deterioration of the reflectance even under the severe conditions such as those for the hydrogen sulfide-exposure test when a quite thin capping layer is applied onto the Ag-alloy film. Accordingly, the present invention may be applied to, for instance, reflection films used for display devices and optics-relating reflection films. In addition, the Ag-alloy film provided thereon with a capping layer is a film excellent in the corrosion resistance, while maintaining its high reflectance and therefore, the film of the present invention can be used in the fields of, for instance, highly reflective films for use in optics, backlights, reflection films for use in the LCD, and reflecting electrode films used in LCD and organic EL.

1. An Ag-based reflection film consisting of a laminate film, which comprises an Ag or Ag-alloy film and a quite thin capping layer applied onto the Ag or Ag-alloy film.

2. The Ag-based reflection film as set forth in claim 1, wherein a film component is selected from the group consisting of pure Ag, Ag/Au alloy, Ag/Au/Sn alloy, Ag/Pd alloy and Ag/Pd/Cu alloy.

3. The Ag-based reflection film as set forth in claim 1, wherein a film component is an Ag/Au/Sn alloy, which comprises Ag as a principal component, 0.1 to 4.0 at % of Au and 0.1 to 2.5 at % of Sn.

4. The Ag-based reflection film as set forth in claim 3, wherein the Ag/Au/Sn alloy film further comprises oxygen in an amount ranging from 0.1 to 3.0 at %.

5. The Ag-based reflection film as set forth in claim 1, wherein the thickness of the capping layer ranges from 3 to 50 nm.

6. The Ag-based reflection film as set forth in any one of claims 1 to 5, wherein the capping layer is a film constructed from a material selected from the group consisting of metal oxides such as ITO, ZnO, IZO and SnO₂, silicon oxide, aluminum oxide, titanium oxide, tantalum oxide, silicon nitride, aluminum nitride, titanium nitride and tantalum nitride.

7. The Ag-based reflection film as set forth in claim 6, wherein when the capping layer is a film constituted by the foregoing metal oxide, the thickness of the capping layer is not less than 3 nm and less than 15 nm.

8. The Ag-based reflection film as set forth in claim 1, wherein the capping layer is a film prepared according to any one of the vacuum process selected from the group consisting of the vacuum evaporation technique, the sputtering technique and the CVD technique.

9. The Ag-based reflection film as set forth in claim 1, wherein the Ag-based reflection film is subjected to an after-annealing treatment carried out in the air, in a vacuum, or in an inert gas atmosphere.

10. A method for the p reparation of an Ag-based reflection film comprising the steps of forming, on the surface of a substrate, an Ag or Ag-alloy film according to the sputtering technique, while using a sputtering target having a composition selected from the group consisting of pure Ag, Ag/Au alloy, Ag/Au/Sn alloy, Ag/Pd alloy and Ag/Pd/Cu alloy or corresponding to that of the Ag/Au/Sn type alloy film or Ag/Au/Sn type alloy which comprises Ag as a principal component, 0.1 to 4.0 at % of Au and 0.1 to 2.5 at % of Sn and a sputtering gas consisting of Ar gas, while adding, as an additional gas, at least one oxygen-containing gas selected from the group consisting of O₂, H₂O, and H₂+O₂ only at the initial stage of the Ag or Ag-alloy film-forming step; and then forming a quite thin capping layer, on the Ag or Ag-alloy film thus formed, according to the sputtering technique, while using a sputtering target having a composition selected from the group consisting of metal oxides such as ITO, ZnO, IZO and SnO₂, silicon oxide, aluminum oxide, titanium oxide, tantalum oxide, silicon nitride, aluminum nitride, titanium nitride and tantalum nitride and a sputtering gas consisting of Ar gas, while if necessary adding, as an additional gas, at least one gas selected from the group consisting of O₂, H₂O, H₂+O₂ and N₂.

11. The method as set forth in claim 10, wherein the Ag-based reflection film is subjected to an annealing treatment carried out in the air, in a vacuum, or in an inert gas atmosphere, after the formation of the quite thin capping layer.
